(19) United States
(12) Patent Application Publication
(10) Pub. No.: US 2024/0036264 A1
(43) Pub. Date: Feb. 1, 2024

(54) MEMS OPTICAL SWITCH HAVING LOW INSERTION SWITCH LOSS

(71) Applicant: II-VI Delaware, Inc., Wilmington, DE (US)

(72) Inventors: Yang Li, Fuzhou (CN); Lixun Chen, Fuzhou (CN); Tianguo Bai, Fuzhou (CN); Wade Tang, Fuzhou (CN); Yunbing Xu, Fuzhou (CN); Tingyu Xue, Fuzhou (CN)

(21) Appl. No.: 18/169,112

(22) Filed: Feb. 14, 2023

(30) Foreign Application Priority Data
Jul. 29, 2022 (CN) 202210909912.5

(51) Int. Cl. G02B 6/35; G02B 6/32; B81B 7/02

(52) U.S. Cl. CPC G02B 6/3518; G02B 6/32; B81B 7/02; G02B 6/3582; B81B 2201/045

(57) ABSTRACT

An optical switch includes an array of optical fibers to conduct optical signals. A biconvex lens has a front convex surface facing the fibers' tips and has a back convex surface facing a microelectromechanical (MEMS) mirror. The MEMS mirror can be selectively oriented to reflect the optical signals incident to the MEMS mirror so the optical signal input from one fiber can be selectively routed to another of the fibers.

### BACKGROUND OF THE DISCLOSURE

The present application claims priority to Chinese Patent Application No. 202210909912.5 filed Jul. 29, 2022. The aforementioned application is hereby incorporated by reference in its entirey.

### BACKGROUND OF THE DISCLOSURE

Various types of optical switches are available. Of these, a Micro-Electromechanical Systems (MEMS) optical switch provides several advantages, including lower optical losses, a small size, and fast switching times. In an existing MEMS optical switch, fibers conduct optical signals to a MEMS mirror, which can be directed to reflect the incident optical signal from one fiber to another selected fiber. The fibers can be arranged in a two-dimensional fiber array for use with a signal MEMS mirror, and a collimator is used to image the optical signals between the fibers and the MEMS mirror.

For instance, FIG. 1 illustrates a schematic view of a MEMS optical switch 10 according to the prior art. As shown, the optical switch has fibers 12, a collimator lens 30, and a MEMS mirror 14. The fibers 12 are arranged in an optical fiber head 20, which has an oblique end 22 to reduce reflection. The collimator lens 30 includes an oblique surface 32 in optical communication with the fibers 12 and also includes a convex surface 34 in optical communication with the MEMS mirror 14. As is typical and as shown in FIG. 1, the collimator lens 30 includes an oblique end or interface.

An optical signal conducted along one fiber is imaged from the fiber tip to the lens 30, which images the optical signal toward the lens' focal plane at the MEMS mirror 14. The MEMS mirror 14 reflects the incident optical signal, and the returning optical signal is then imaged into the selected fiber 12 for output.

A schematic view of another MEMS optical switch 10 is shown in FIG. 2. Here, the optical switch 10 uses two collimation lenses 30, 40 between the fibers 12 and the MEMS mirror 14. An example of this arrangement is disclosed in CN 210038236. Overall, the two collimation lenses 30, 40 can reduce the large differences in insertion loss for the channel, which are caused by large spherical aberration. However, the increased number of lenses 30, 40 requires a larger package, more complicated alignment and fabrication, and increased production costs. Moreover, for wide spectrum applications, the large wavelength-dependent loss can be an issue as well.

The subject matter of the present disclosure is directed to overcoming, or at least reducing the effects of, one or more of the problems set forth above.

### SUMMARY OF THE DISCLOSURE

As disclosed herein, an optical switch for optical signals comprises a plurality of optical fibers, a biconvex lens, and a microelectromechanical (MEMS) mirror. The optical fibers are configured to conduct the optical signals and are oriented in an array along an optical axis, each fiber having a fiber tip. The biconvex lens is disposed on the optical axis and has front and back convex surfaces opposing one another. The front convex surface faces the fiber tips. The MEMS mirror is disposed on the optical axis and faces the back convex surface of the biconvex lens. The MEMS mirror is selectively orientable to reflect the optical signals incident thereto.

As disclosed herein, an optical switch for optical signals comprises a housing, a fiber head, a plurality of optical fibers, a biconvex lens, and a microelectromechanical (MEMS) mirror. The housing defines an optical axis, and the fiber head is disposed in the housing and has an interface surface. The optical fibers are disposed in the fiber head and are oriented in an array along the optical axis. The optical fibers are configured to conduct the optical signals, and each has a fiber tip exposed at the interface surface. The biconvex lens is disposed in the housing on the optical axis and has front and back convex surfaces opposing one another. The front convex surface faces the fiber tips. The MEMS mirror is disposed in the housing on the optical axis and faces the back convex surface of the biconvex lens. The MEMS mirror is selectively orientable to reflect the optical signals incident thereto.

An insert composed of optical glass can be disposed between the interface surface of the fiber head and the front convex surface of the biconvex lens. The insert can have an oblique face and a normal face. The oblique face is defined at an oblique angle with respect to the optical axis and faces the interface surface. The normal face is defined normal with respect to the optical axis and faces the front convex surface.

A method is disclosed herein and comprises: conducting at least one optical signal in at least one of a plurality of optical fibers arranged in an array along an optical axis; imaging the at least one optical signal from a fiber tip of the at least one optical fiber to a front convex surface of a biconvex lens disposed on the optical axis; imaging the at least one optical signal from a back convex surface of the biconvex lens to a microelectromechanical (MEMS) mirror disposed on the optical axis; and reflecting the at least one optical signal incident to the MEMS mirror back through the biconvex lens to a selected one of the optical fibers arranged in the array by selectively orienting the MEMS mirror.

The foregoing summary is not intended to summarize each potential embodiment or every aspect of the present disclosure.

### BRIEF DESCRIPTION OF THE DRAWINGS

FIG. 1 illustrates a schematic view of an optical switch according to the prior art.

FIG. 2 illustrates a schematic view of another optical switch according to the prior art.

FIG. 3 illustrates a schematic view of an optical switch according to the present disclosure.

FIG. 4 illustrates a schematic view of another optical switch according to the present disclosure.

FIG. 5 illustrates a schematic view of the optical switch having housing components.

FIGS. 6A-6B illustrate end views of example array arrangements for the fibers in the fiber head for the disclosed optical switch.

FIGS. 7A-7D illustrate schematic views of the optical switch having different housing packages.

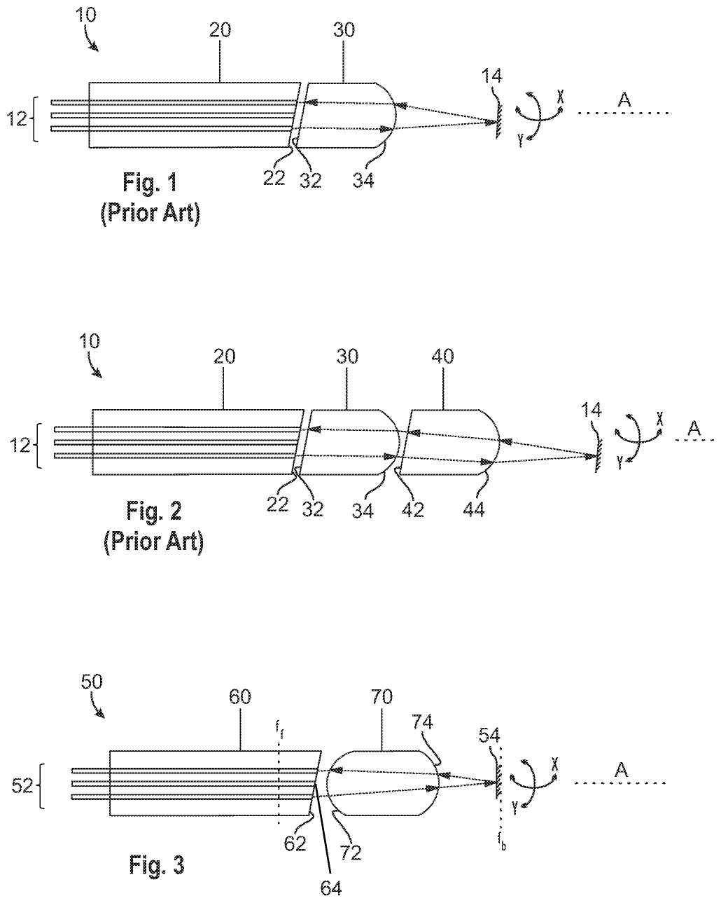

### DETAILED DESCRIPTION OF THE DISCLOSURE

FIG. 3 illustrates a schematic view of an optical switch 50 according to the present disclosure. The optical switch 50 is used for switching optical signals between at least one input and two or more outputs. These optical signals can be defined within different wavelength channels, such as those used in wavelength division multiplexing (WDM).

The optical switch 50 includes a plurality of optical fibers 52, a biconvex lens 70, and a microelectromechanical (MEMS) mirror 54. The optical fibers 52 are oriented in an array along an optical axis A. For example, the optical fibers 52 can be held in a fiber head 60, which organizes the fibers 52 side-by-side at a pitch in a one-dimensional or a two-dimensional array. The fiber head 60 has an interface 62 at which fiber tips 64 of the optical fibers 52 are exposed. The optical fiber head 60 may include, for example, one or more glass structures for positioning and arranging the optical fibers 52. Preferably, the interface 62 is defined at an oblique angle relative to the optical axis A, which can reduce reflections.

The biconvex lens 70 is disposed on the optical axis A and has front and back convex surfaces 72, 74 opposing one another. The front convex surface 72 faces the fiber tips 64 of the optical fibers 52, and the back convex surface 74 faces the MEMS mirror 54, which is also disposed on the optical axis A. Although only schematically shown, the MEMS mirror 54 includes a micro-mirror and a micro-electromechanical system that can change the orientation of the micro-mirror. Being arranged between the fibers 52 and the MEMS mirror 54, the biconvex lens 70 has a front focal plane f_{f} towards the fiber tips 64 and has a back focal plane f_{b} towards the MEMS mirror 54 to image the optical signals therebetween.

During operation, the MEMS mirror 54 is selectively orientable to reflect the optical signals incident to the MEMS mirror 54. For example, if the fiber array is one-dimensional, the orientation of MEMS mirror 54 can be changed in one axis X to switch an incident optical signal from an input one of the optical fibers 52 to one of the other optical fibers 52 in the one-dimensional array. Meanwhile, if the fiber array is two-dimensional, the orientation of the MEMS mirror 54 can be changed in two axes X, Y to switch the incident optical signal from an input one of the optical fibers 52 to one of the other optical fibers 52 in the two-dimensional array. In this way, using the angular rotation of the MEMS mirror 54, optical signals can be freely switched between the fibers 52 of the fiber array.

During operation, at least one input optical signal is conducted in at least one of the optical fibers 52 arranged in the array along the optical axis A. In a general sense, any one of the optical fibers 52 can be an input fiber that provides an input optical signal, and any of the optical fibers 52 can be an output fiber to which the input optical signal can be switched for the purposes of optical switching for an application at hand. Alternatively, various fibers 52 can be separately designated for input or output. The input optical signal is imaged from the fiber's tip to the front convex surface 72 of the biconvex lens 70. Passing through the lens 70, the input signal is imaged from the back convex surface of the biconvex lens 70 to the MEMS mirror 54. In turn, the MEMS mirror 54 is controllable to selectively reflect the optical signal incident thereto from the input fiber 52 to a selected one of the output fibers 52.

The optical fibers 52 can include any appropriate type of optical fiber for the application at hand, and the fiber head 60 can be composed of an appropriate optical glass or another common material. Preferably, the biconvex lens 70 is made of a low dispersion optical material, such as a flint glass, a dense tantalum flint, a lanthanum dense flint, or the like. The material for the biconvex lens 70 preferably has a high refractive index (e.g., greater than 1.7) and low dispersion properties. One particular material is the dense tantalum flint, TAFD40, available from the HOYA Corporation. The pitch (between the fibers 54), the axial distances (between the fiber tips 64, biconvex lens 70, and the MEMS mirror 54), and the size and focal planes (of the biconvex lens 70) can be configured to correct for aberration in the optical switch 50 and to improve insertion loss. The biconvex lens 70 can be symmetrical. Alternatively, the biconvex lens 70 can be asymmetrical with different focal lengths for the front and back focal planes, according to the different optical path lengths and channel numbers.

As configured, the biconvex lens 70 along with its low dispersion material can reduce insertion loss of the optical signals. In this way, differences in insertion loss between different channels of the optical signals and wavelength-dependent loss in the optical switch 50 can be effectively reduced.

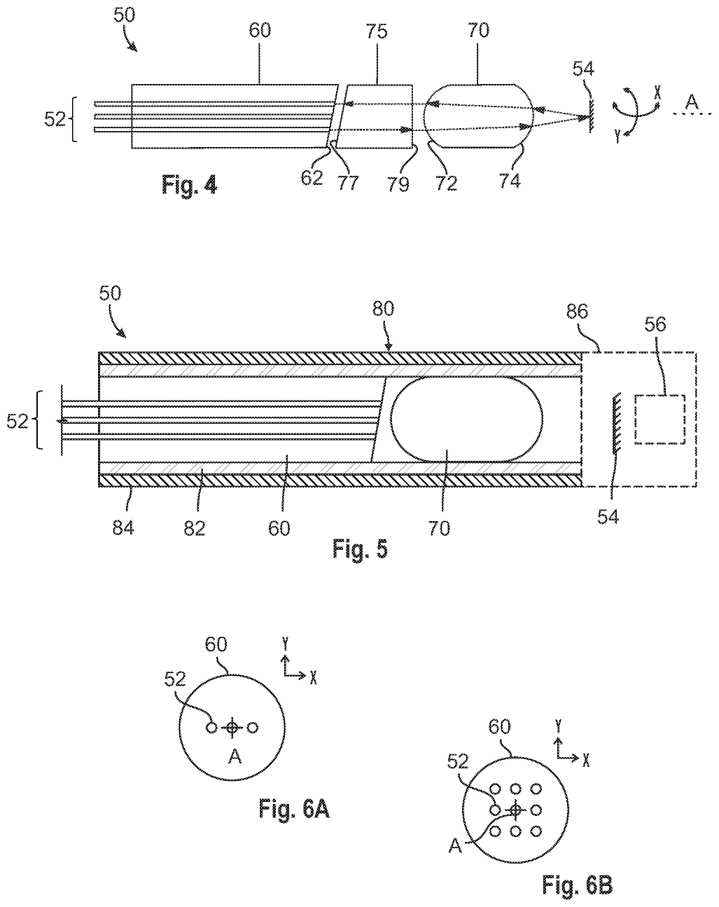

FIG. 4 illustrates a schematic view of another optical switch 50 according to the present disclosure. This optical switch 50 is similar to that disclosed above so that the same reference numerals are used for similar components. Here, an optical insert 75 is positioned between the fiber head 60 and the biconvex lens 70. The optical insert 75 can be a section of a rod of optical glass. As shown, the optical insert 75 can include an oblique face 77 adjacent the fiber head's oblique interface 62. Meanwhile, the insert 75 includes a normal face 79 directed to the biconvex lens 70. The insert 75 can be added to ensure that the light output is horizontal.

The components of the optical switch 50 can be arranged and housed as necessary for the particular implementation. In general, the optical switch 50 uses a housing to hold the components, and the housing can be incorporated into a larger device or system that uses the optical switch 50. For example, FIG. 5 illustrates a schematic view of the optical switch 50 having a housing 80, which fixes the distances and the alignment between the optical fibers 52, the lens 70, and the MEMS mirror 54.

As shown here, the housing 80 can include a glass enclosure, sleeve, or tube 82 in which at least the biconvex lens 70 and the fiber head 60 are installed. Appropriate affixing can be used, such as an epoxy or the like, to hold the lens 70 and head 60 in place. The glass enclosure 82 can in turn be installed in a rigid enclosure, sleeve, or tube 84 to provide structural support and optical isolation. The rigid enclosure 84 can be composed of metal, for example.

The MEMS mirror 54 has a driver 56 that is electrically driven to mechanically change the orientation of the micro-mirror of the MEMS mirror 54. Depending on the size of the MEMS mirror 54 and the driver 56, they can be housed in the enclosures 82, 84. Alternatively, a separate enclosure 86 of the housing 80 can hold the MEMS mirror 54 and the driver 56 and can be connected to the other enclosures 82, 84 to form the housing 80. This and a number of other arrangements can be used.

As noted, the optical fibers 52 can be arranged in a one-dimensional or two-dimensional array. For example, the fiber array can have the optical fibers 52 arranged in a 1-by-M, an M-by-M, or an M-by-N arrangement. Any number of fibers 52 can be used, and only a few fibers 52 are shown in the illustrated configurations merely as examples.

FIGS. 6A-6B illustrate end views of example array arrangements for optical fibers 52 in a fiber head 60 for the disclosed optical switch. FIG. 6A shows a one-dimensional array of the fibers 52 disposed in one axis (X-axis) relative to the optical axis A. Meanwhile, FIG. 6B shows a two-dimensional array of the fibers 52 disposed in two axes (X, Y-axes) relative to the optical axis A. As seen from the end view, the fiber head 60 can be cylindrical, but other configurations can be used. Additionally, any suitable arrangement and number of fibers 52 can be used, and they are preferably arranged symmetrically relative to the optical axis.

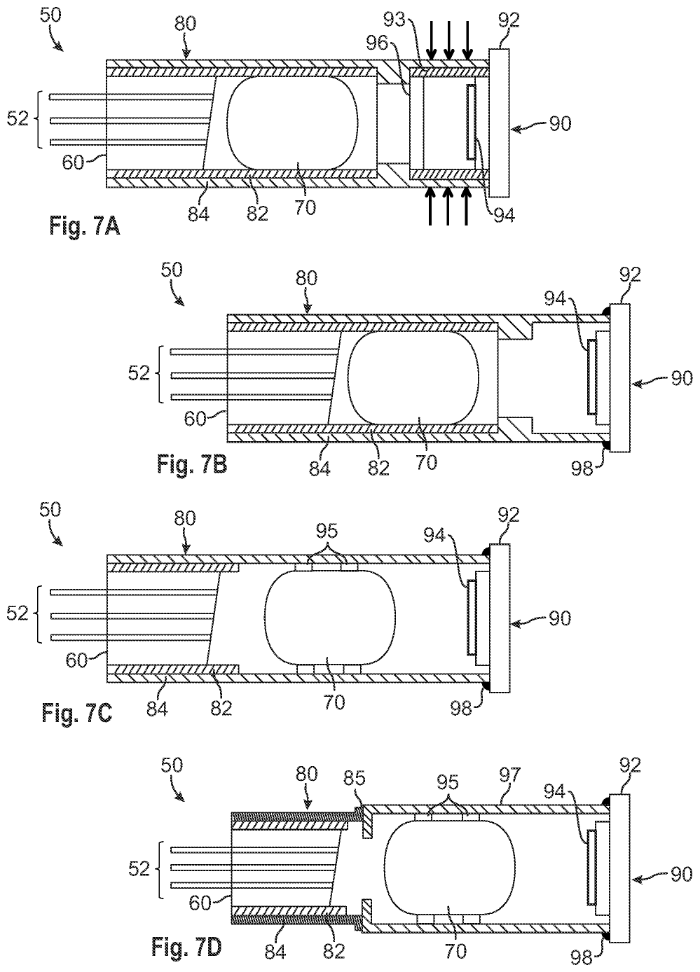

FIGS. 7A-7D illustrate schematic views of the optical switch having different housing packages. The same reference numerals for components comparable to those disclosed above are also shown in FIGS. 7A-7D.

The optical switch 50 in FIG. 7A shows the housing 80 laser welded to a Transistor Outline (TO) package 90. The TO package 90 has a header 92 that holds a MEMS chip 94. A window plate 96 is disposed on a cap 93, which is attached to the header 92 of the TO package 90. The housing's outer enclosure 84 of metal material is laser welded to the cap 93 of the TO package 90. This configuration can provide good sealing performance. A ghost image may be caused by the window plate 96 for a hitless position of the MEMS chip 94.

In the example of FIG. 7B, the housing 80 is affixed by resistance welding or an epoxy seal 98 to the TO package 90, which may not include a cap and a window plate. In particular, the outer enclosure 84 is affixed by the resistance welding or the epoxy seal 98 to the header 92. Lacking a window plate, this configuration may not suffer from the problem of a ghost image, but the sealing performance may not be as good as the laser-welded configuration in FIG. 7A.

The optical switch 50 in FIG. 7C uses coaxial packaging with induction welding. The outer enclosure 84 of the housing 80 is affixed by resistance welding or an epoxy seal 98 to the header 92 of the TO package 90. The biconvex lens 70 is fixed by induction welding 95 in the outer enclosure 84. Lacking a window plate, this configuration does not suffer from the ghost image problem, and the configuration has good sealing performance. Attention may be needed during assembly for the orientation (tilt) of the biconvex lens 70.

The optical switch 50 in FIG. 7D uses yet another form of coaxial packaging. The biconvex lens 70 is fixed by induction welding 95 in a metal sleeve 97, which is affixed by resistance welding or an epoxy seal 98 to the header 92 of the TO package 90. The metal sleeve 97 and the outer enclosure 84 are affixed together by laser welding 85. Lacking a window plate, this configuration does not suffer from the ghost image problem, and the configuration has good sealing performance. Also, adjustments can be made in the radial direction between the housing's components 97 and 84 before affixing. Again, attention may be needed during assembly for the orientation (tilt) of the biconvex lens 70.

The foregoing description of preferred and other embodiments is not intended to limit or restrict the scope or applicability of the inventive concepts conceived of by the Applicants. It will be appreciated with the benefit of the present disclosure that features described above in accordance with any embodiment or aspect of the disclosed subject matter can be utilized, either alone or in combination, with any other described feature, in any other embodiment or aspect of the disclosed subject matter.

In exchange for disclosing the inventive concepts contained herein, the Applicants desire all patent rights afforded by the appended claims. Therefore, it is intended that the appended claims include all modifications and alterations to the full extent that they come within the scope of the following claims or the equivalents thereof.

What is claimed is:

1. An optical switch for optical signals, the optical switch comprising:
a plurality of optical fibers configured to conduct the optical signals and being oriented in an array along an optical axis, each fiber having a fiber tip;
a biconvex lens disposed on the optical axis and having front and back convex surfaces opposing one another, the front convex surface facing the fiber tips; and
a microelectromechanical (MEMS) mirror disposed on the optical axis and facing the back convex surface of the biconvex lens, the MEMS mirror being selectively orientable to reflect the optical signals incident thereto.

2. The optical switch of claim 1, comprising a fiber head holding the plurality of optical fibers in the array, the fiber tips exposed at an interface surface of the fiber head.

3. The optical switch of claim 2, further comprising a housing enclosing the fiber head, the biconvex lens, and the MEMS mirror.

4. The optical switch of claim 2, wherein the interface surface of the fiber head is defined at a first oblique angle with respect to the optical axis.

5. The optical switch of claim 4, further comprising an insert composed of optical glass disposed between the interface surface of the fiber head and the front convex surface of the biconvex lens, the insert having an oblique face and a normal face, the oblique face defined at a second oblique angle with respect to the optical axis and facing the interface surface, the normal face defined normal with respect the optical axis and facing the front convex surface.

6. The optical switch of claim 1, wherein the array comprises a two-dimensional array of the optical fibers.

7. The optical switch of claim 1, wherein the biconvex lens comprises a low dispersion optical material, a flint glass, a dense tantalum flint, or a lanthanum dense flint.

8. The optical switch of claim 1, wherein the front convex surface comprises a front focal plane towards the fiber tips; and wherein the back convex surface comprises a back focal plane towards the MEMS mirror.

9. The optical switch of claim 1, wherein at least one of the optical fibers is an input fiber; wherein each of at least two of the optical fibers is an output fiber; and wherein the MEMS mirror is controllable to selectively direct the optical signal incident thereto from the input fiber to a selected one of the output fibers.

10. An optical switch for optical signals, the optical switch comprising:
a housing defining an optical axis;
a fiber head disposed in the housing and having an interface surface;
a plurality of optical fibers disposed in the fiber head and oriented in an array along the optical axis, the optical fibers being configured to conduct the optical signals and each having a fiber tip exposed at the interface surface;
a biconvex lens disposed in the housing on the optical axis and having front and back convex surfaces opposing one another, the front convex surface facing the fiber tips; and
a microelectromechanical (MEMS) mirror disposed in the housing on the optical axis and facing the back convex surface of the biconvex lens, the MEMS mirror being selectively orientable to reflect the optical signals incident thereto.

11. The optical switch of claim 10, wherein the interface surface of the fiber head is defined at an oblique angle with respect to the optical axis.

12. The optical switch of claim 10, wherein the array comprises a two-dimensional array of the optical fibers.

13. The optical switch of claim 10, wherein the biconvex lens comprises a low dispersion optical material, a flint glass, a dense tantalum flint, or a lanthanum dense flint.

14. The optical switch of claim 10, wherein the front convex surface comprises a front focal plane towards the fiber tips; and wherein the back convex surface comprises a back focal plane towards the MEMS mirror.

15. The optical switch of claim 10, wherein at least one of the optical fibers is an input fiber; wherein each of at least two of the optical fibers is an output fiber; and wherein the MEMS mirror is controllable to selectively direct the optical signal incident thereto from the input fiber to a selected one of the output fibers.

16. The optical switch of claim 10, further comprising an insert composed of optical glass disposed between the interface surface of the fiber head and the front convex surface of the biconvex lens, the insert having an oblique face and a normal face, the oblique face defined at a second oblique angle with respect to the optical axis and facing the interface surface, the normal face defined normal with respect the optical axis and facing the front convex surface.

17. The optical switch of claim 10, wherein the housing comprises:
a glass enclosure having the fiber head and the biconvex lens disposed therein;
a metal enclosure having the glass enclosure disposed therein, the metal enclosure having first and second ends, the first end having the optical fibers extending therefrom; and
at least a portion of a transistor outline package affixed to the second end of the metal enclosure.

18. A method, the method comprising:
conducting at least one optical signal in at least one of a plurality of optical fibers arranged in an array along an optical axis;
imaging the at least one optical signal from a fiber tip of the at least one optical fiber to a front convex surface of a biconvex lens disposed on the optical axis;
imaging the at least one optical signal from a back convex surface of the biconvex lens to a microelectromechanical (MEMS) mirror disposed on the optical axis; and
reflecting the at least one optical signal incident to the MEMS mirror back through the biconvex lens to a selected one of the optical fibers arranged in the array by selectively orienting the MEMS mirror.

19. The method of claim 18, comprising holding the optical fibers of the array in a fiber head, the fiber tips exposed at an interface surface of the fiber head.

20. The method of claim 19, further comprising enclosing the fiber head, the biconvex lens, and the MEMS mirror in a housing.

21. The method of claim 19, wherein imaging the at least one optical signal from the fiber tip of the at least one optical fiber comprises imaging the at least one optical signal from the interface surface defined at an oblique angle with respect to the optical axis.

22. The method of claim 18, wherein the array comprises a two-dimensional array of the optical fibers.

23. The method of claim 18, comprising providing the biconvex lens made of a low dispersion optical material, a flint glass, a dense tantalum flint, or a lanthanum dense flint.
